(19) United States
(12) Patent Application Publication
(10) Pub. No.: US 2006/0088962 A1
(43) Pub. Date: Apr. 27, 2006

(54) Method of forming a solution processed transistor having a multilayer dielectric

(76) Inventors: Gregory S. Herman, Albany, OR (US); Peter Mardilovich, Corvallis, OR (US); Randy Hoffman, Corvallis, OR (US); Laura Kramer, Corvallis, OR (US); Kurt Ulmer, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/972,229

(22) Filed: Oct. 22, 2004

(51) Int. Cl. H01L 21/00

(52) U.S. Cl. 438/151

(57) ABSTRACT

Embodiments of methods, apparatuses, devices, and/or systems for forming a solution processed transistor having a multilayer dielectric are described.

### BACKGROUND

Electronic devices, such as integrated circuits, smart packages and electronic displays, for example, may comprise one or more components, such as one or more thin film transistors (TFTs). Methods and/or materials utilized to form devices and/or components such as these may vary, and one or more of these methods and/or materials may have particular disadvantages. For example, use of such methods and/or materials may be time-consuming and/or expensive, may preclude the use of particular materials, and/or may not produce devices and/or components having the desired characteristics.

### BRIEF DESCRIPTION OF THE DRAWINGS

Subject matter is particularly pointed out and distinctly claimed in the concluding portion of the specification. Claimed subject matter, however, both as to organization and method of operation, together with objects, features, and advantages thereof, may best be understood by reference of the following detailed description when read with the accompanying drawings in which:

FIG. 1 is a cross sectional view of one embodiment of a TFT;

FIG. 2 is a cross sectional view of one embodiment of a TFT; and

FIG. 3 is a flowchart illustrating one embodiment of a method to form a TFT.

### DETAILED DESCRIPTION

In the following detailed description, numerous specific details are set forth to provide a thorough understanding of claimed subject matter. However, it will be understood by those skilled in the art that claimed subject matter may be practiced without these specific details. In other instances, well-known methods, procedures, components and/or circuits have not been described in detail so as not to obscure claimed subject matter.

Electronic devices, such as semiconductor devices, display devices, nanotechnology devices, conductive devices, and dielectric devices, for example, may comprise one or more electronic components. The one or more electronic components may comprise one or more thin film components, which may be comprised of one or more thin films. In this context, the term thin film refers to a layer of one or more materials formed to a thickness, such that surface properties of the one or more materials may be observed, and these properties may vary from bulk material properties. Thin films may additionally be referred to as component layers, and one or more component layers may comprise one or more layers of material, which may be referred to as material layers, for example. The one or more material and/or component layers may have particular electrical and chemical properties, such as conductivity, chemical interface properties, charge flow, and/or processability, for example. The one or more material and/or component layers may additionally be patterned, for example. The one or more material and/or component layers, in combination with one or more other material and/or component layers may form one or more electrical components, such as thin film transistors (TFTs), capacitors, diodes, resistors, photovoltaic cells, insulators, conductors, optically active components, or the like. Components such as TFTs, in particular, may, for example, be utilized in devices including smart packages and/or display devices including, for example, radio frequency identification (RFID) tags, one or more types of sensors, and electroluminescent and/or liquid crystal displays (LCD), such as active matrix liquid crystal display (AMLCD) devices, for example.

At least as part of the fabrication process of electronic components such as thin film components, including, for example, thin film transistors, one or more layers of material may be formed at least as part of one or more of the component layers. One or more component layers may comprise a channel layer, one or more electrodes, and/or a dielectric layer, if the thin film component comprises a thin film transistor, for example. In one embodiment, as at least a part of the fabrication process, one or more material layers may be formed by use of one or more formation processes, and/or by use of one or more materials, such as a combination of materials, for example. In one particular embodiment, at least a portion of a component, such as a thin film component, may be formed by use of one or more processes. At least one of the processes may be referred to as solution processing, for example. Solution processing, as used in this context, comprises one or more processes, wherein a solution, such as a substantially liquid solution, and/or a solid or solid precursor that may be at least partially dissolved in a liquid, for example, may be deposited on one or more surfaces of a component, such as on one or more surfaces of a substrate, by use of one or more deposition processes. Components, such as electronic components, including TFTs, for example, which may be at least partially formed by one or more processes such as solution processes may be referred to as solution processed components, for example. In one embodiment of solution processing, an ejection mechanism, such as an ink jet device, may deposit and/or jet one or more materials, such as a liquid, onto a surface, in order to substantially form a material layer, for example. Additionally, one or more spin coating processes and/or one or more contact printing processes, wherein one or more printing devices may be capable of printing materials, such as liquid materials, on to a surface, may be utilized in one or more embodiments of solution processing, although these are just a few examples, and claimed subject matter is not so limited. For example, one or more dip coating processes, spray coating processes, curtain coating processes, screen printing processes, chemical bath deposition processes and/or successive ionic layer absorption and reaction processes may be utilized in one or more embodiments of solution processing. Additionally, as used herein, an ejection device, such as a jetting device, including an ink jet device capable of performing ink jetting, may comprise a mechanism capable of ejecting material such as liquid, including a solution, for example, and may eject material in the form of drops, for example, such as mechanically and/or electrically, and/or in response to electrical signals, and may be capable of ejecting material in controlled portions, in a controlled manner, and/or in a controlled direction, for example. Additionally, an ejection device may operate by use of one or more ejection schemes, including piezo ejection, thermal ejection, continuous ejection, acoustic ejection and/or flex tensioned ejection, for example, but, again, claimed subject matter is not limited to these examples.

Although claimed subject matter is not so limited, in one particular embodiment, an electronic component, such as a thin film component, may comprise at least one component layer, wherein the at least one component layer comprises two or more layers of material, such as differing material and/or material having differing characteristics, for example. In at least one embodiment, at least a portion of the component may be conductive, semiconductive, and/or insulative, for example, and, in at least one embodiment, a dielectric layer may be formed as part of a component, wherein the dielectric layer comprises at least two material layers. In this embodiment, at least two of the material layers may substantially comprise inorganic material, for example. It is worthwhile to note that claimed subject matter is not limited in scope to a component having two material layers, and/or a component layer comprising two layers of inorganic material. For example, one or more layers of material may be formed between the at least two inorganic material layers, such as additional inorganic material layers, for example, and use of additional material layers other than the at least two inorganic layers may depend at least in part on the particular component being formed, for example.

Formation of a component such as a thin film transistor having a dielectric layer, wherein the dielectric layer comprises two or more inorganic material layers may provide a component having one or more desirable characteristics, such as one or more characteristics that a component not having two or more inorganic material layers may not have, for example. In one embodiment, the two or more inorganic material layers may comprise differing materials, and/or may have differing properties, such as differing physical, chemical and/or electrical properties, including, for example, electrical interface properties, breakdown field properties and/or current leakage properties, as just a few examples, which may affect semiconductor properties such as mobility, stability and/or turn-on voltages. Additionally, one or more of these materials may have particular advantages and/or disadvantages with reference to deposition. For example, in one embodiment, inorganic materials that may exhibit one or more desirable characteristics, such as desirable chemical and/or electrical interface characteristics, such as desirable film quality, dielectric strength, and/or charge transport properties, which may aid reliability, for example, may be comparatively difficult to process, such as by necessitating the use of high temperature processing. Conversely, one or more types of inorganics, including amorphous and/or glass-like inorganic materials may be more readily processed, but may not exhibit desirable properties including electrical interface properties, for example. In this context, the term glass-like refers generally to a material having one or more properties of glass, such as control over viscosity, remaining substantially non-crystalline when solidified, and insulating, for example. In at least one embodiment, the two or more inorganic materials may have differing properties, such as by one material having one or more desirable electrical interface properties, but not having particularly desirable electrical integrity properties and/or processability, for example, and by a second material having one or more desirable electrical integrity properties and or processability, but not having particularly desirable electrical interface properties, as just an example. Utilization of at least these two materials may provide the capability to select the differing materials, material configurations and/or processes to produce a component having desirable characteristics, such as by forming a dielectric layer by depositing a first dielectric material having one or more desired electrical interface properties on a channel layer by use of one or more processes, whereby a dielectric layer/channel layer interface is formed, and depositing a second dielectric material having one or more desired electrical properties over at least a portion of the first dielectric material by use of one or more processes, as just one potential example. Thus, a dielectric layer may be formed from two or more inorganic materials and/or by use of two or more processes, wherein the dielectric layer may exhibit one or more properties that a dielectric layer not formed from two or more inorganic materials may not exhibit, for example.

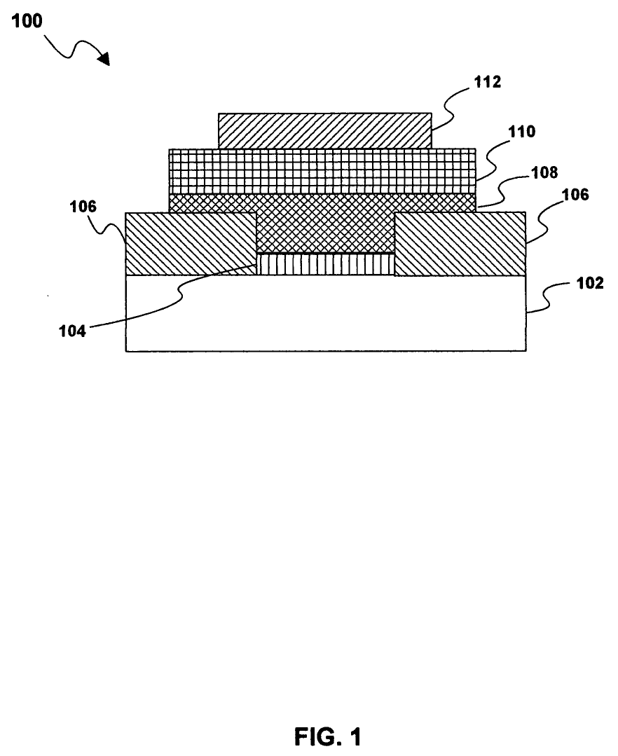

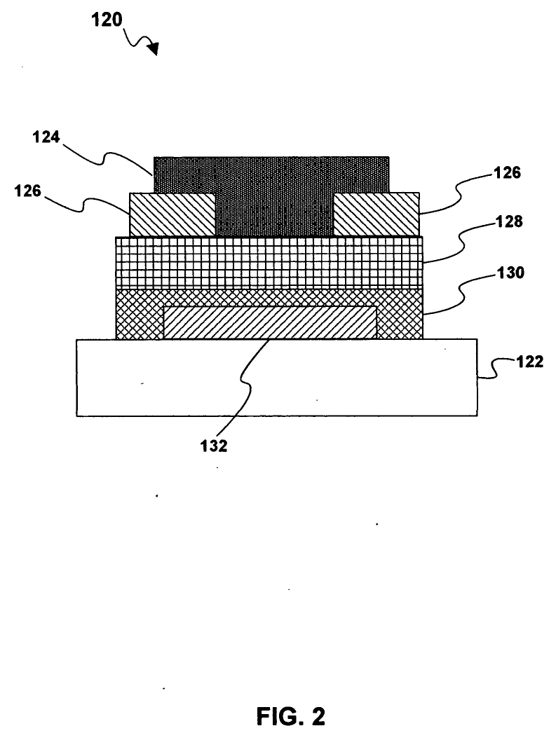

Referring now to FIG. 1, there is illustrated a cross-sectional view of one embodiment 100 of an electronic component in a stage of formation. Electronic component 100, here, may comprise an electronic component formed by use of one or more deposition processes, such as solution processes, for example, and may comprise a portion of a display device, such as a portion of an active-matrix liquid crystal display (AMLCD) device, such as a backplane, and/or a portion of a smart package, such as an RFID tag, as just a few examples. Embodiment 100, here, comprises substrate 102, with one or more component layers 104, 106, 108, 110 and/or 112 formed thereon. In one particular embodiment, component layer 104 may comprise a channel layer; component layer 106 may comprise an electrode layer, and may further comprise one or more drain and/or source electrodes, for example; component layer 108 may comprise a first portion of a dielectric layer; component layer 110 may comprise a second portion of a dielectric layer, wherein said first and second portions may be formed from inorganic material, such as differing inorganic materials, as explained previously; and component layer 112 may comprise a conducting gate layer, which may include a gate electrode, for example. Additionally, one or more of the source and/or drain electrodes 106 may be electrically coupled to the channel layer 104, and at least a portion of the conducting gate layer 112 may be electrically coupled to one or more portions 108 and/or 110 of the dielectric layer, and, in this particular configuration, component 100 may be referred to as a top gate thin film transistor, which may refer to a transistor configured to have a gate layer formed on or over a dielectric layer, for example, although it is worthwhile to note that this is just one embodiment, and claimed subject matter is not limited in this respect, but may comprise other configurations such as a bottom gate transistor, explained in more detail with reference to FIG. 2. Additionally, it is noted here and throughout this description that claimed subject matter is not limited to the foregoing material and/or component layers being formed on one another. For example, other layers may be included, such as intervening layers formed between various layers, so that layers may be formed above or over one another rather than on one another, depending, for example, on the particular embodiment.

Referring now to FIG. 2, there is illustrated a cross-sectional view of one embodiment 120 of an electronic component in a stage of formation. Electronic component 120, similar to embodiment 100, may comprise an electronic component formed by use of one or more processes and/or materials, such as by forming component 120 to have a dielectric layer comprising two or more inorganic materials, for example, and may comprise a portion of a display device, such as a portion of an AMLCD device, such as a backplane, and/or a portion of a smart package, such as an RFID tag, as just a few examples. Embodiment 120, here, comprises substrate 122, with one or more component layers 124, 126, 128 130 and/or 132 formed thereon. In one particular embodiment, component layer 124 may comprise a channel layer; component layer 126 may comprise an electrode layer, and may further comprise a drain and/or source electrode, for example; component layers 128 and 130 may each comprise a portion of dielectric layer wherein each portion may be formed from inorganic material, such as differing inorganic materials, as explained previously, and component layer 132 may comprise a gate electrode layer, and, in this particular configuration, component 120 may be referred to as a bottom gate thin film transistor, which may refer to a transistor configured to have a gate electrode layer formed on or over a substrate, and a dielectric layer formed over the gate electrode layer, for example. Additionally, similar to embodiment 100, it is noted that claimed subject matter is not limited to the foregoing material and/or component layers being formed on one another. For example, other layers may be included, such as intervening layers formed between various layers, so that layers may be formed above or over one another rather than on one another, depending, for example, on the particular embodiment.

Although claimed subject matter is not limited to any particular material and/or combination of materials to form one or more of the layers and/or components illustrated in FIGS. 1 and/or 2, in at least one embodiment, one or more of the component layers may comprise one or more of the materials described below. Additionally, it is worthwhile to note that claimed subject matter is not limited in this respect, and one or more of the component layers may comprise any material or combination of materials that may be suitable for use as one or more component layers, including materials exhibiting properties suitable for application as one or more component layers in an electronic component, for example. However, in this embodiment, where component layers 102 and/or 122 comprise a substrate layer, component layers 102 and/or 122 comprise may comprise one or more materials suitable for use as a substrate, including, for example, silicon, silicon dioxide, one or more types of glass, one or more organic substrate materials, such as polyimides (PI), including Kapton®, polyethylene terephthalates (PET), polyethersulfones (PES), polyetherimides (PEI), polycarbonates (PC), polyethylenenaphthalates (PEN), acrylics including polymethylmethacrylates (PMMA) and combinations thereof, for example, but claimed subject matter is not so limited. Additionally, substrate layer 102 may also comprise one or more inorganic materials, including silicon, silicon dioxide, one or more types of glass, stainless steel and/or metal foils, including foils of aluminum and/or copper, for example, but claimed subject matter is not so limited. Additionally, in at least one embodiment, wherein a substrate material is substantially comprised of one or more metals, an insulator layer may be utilized in addition to the one or more metals to form the substrate, for example. Additionally, in at least one embodiment, wherein a substrate material is substantially comprised of one or more metals, an insulator layer may be utilized in addition to the one or more metals, for example. Additionally, in this particular embodiment, component layers 104 and/or 124 may comprise channel layers. Component layers 104 and/or 124 may be comprised of one or more materials suitable for use as a channel layer, including, for example, metal oxides such as zinc oxide, tin oxide, indium oxide, gallium oxide, cadmium oxide, lead oxide, copper oxide, silver oxide and combinations thereof; silicon, including amorphous, nanowire, microribbon, and/or polycrystalline silicon; carbon nanotubes, GaAs, Ge, CdS, CdSe, ZnS, ZnSe, SnS₂, SnSe₂, and/or combinations thereof, for example. In this embodiment, wherein component layers 106 and/or 126 comprise electrode layers, and may be comprised of one or more source and/or drain electrodes, for example, at least a portion of component layers 106 and/or 122 may be substantially comprised of indium tin oxide; other doped oxide semiconductors, such as n-type doped zinc oxide, indium oxide, and/or tin oxide, and/or metals, such as Al, Ag, In, Sn, Zn, Ti, Mo, Au, Pd, Pt, Cu, W, Ni and combinations thereof, as just a few examples. Additionally, in this embodiment, wherein component layers 112 and/or 132 comprise gate layers, component layers 112 and/or 132 may be comprised of metals, such as Al, Ag, In, Sn, Zn, Ti, Mo, Au, Pd, Pt, Cu, Ni; indium tin oxide; other doped oxide semiconductors, such as n-type doped zinc oxide, indium oxide, tin oxide, and combinations thereof, as just a few examples.

Continuing with this embodiment, component 100 may comprise a dielectric layer, wherein the dielectric layer may comprise two or more inorganic material layers, illustrated as dielectric layer portion 108 and dielectric layer portion 110. In one embodiment, dielectric layer portion 108 may comprise one or more inorganic materials having one or more properties, such as one or more of the properties described previously. Additionally, dielectric layer portion 110 may comprise one or more inorganic materials having one or more properties, such as one or more of the properties described previously, and one or more of these properties of dielectric layer portion 110 may vary from one or more properties of dielectric layer portion 108, for example. In at least one embodiment, dielectric layer portion 108 may comprise inorganic materials, including SiOₓ, AlOₓ, ZrOₓ, HfOₓ, SiNₓ, SiOₓN_{y}, GeOₓ, GaOₓ, SbOₓ, SnOx, TiOx, YOx, LaOx, BaₐSr_{b}TiOx, BaₐZr_{b}TiOx, TaOₓ, and combinations thereof, as just a few examples. Conversely, dielectric layer portion 110 may comprise one or more other inorganic materials, including amorphous and/or glass-like materials, such as one or more metal-oxy-hydroxy-salts, one or more types of glass, including solution processed silicate glasses, alkaline doped silicate glasses, sodium silicates, phosphosilicates, borosilicates, aluminosilicates, oxycarbide glasses, polysiloxanes, one or more glass resins including silsesquioxanes, hafnium-oxy-hydroxy-sulfate (“Hafsox”) (HfOₓ(OH)_{y}(SO₄)_{z}) and combinations thereof, for example. One particular embodiment of Hafsox, which may be employed by at least one embodiment, is set forth in the following patent application, “Dielectric Material”, application Ser. No. 10/837,411, filed Apr. 30^{th}, 2004, assigned to the assignee of the presently claimed subject matter, although it is worthwhile to note that claimed subject matter is not so limited.

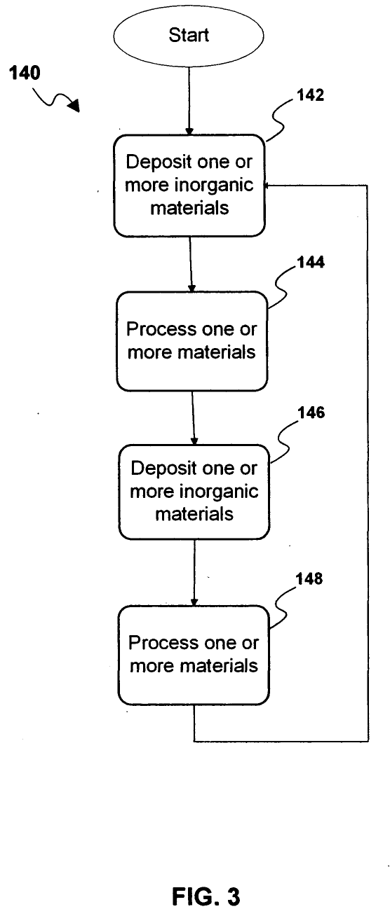

Formation of one or more layers of component 100 of FIG. 1 and/or component 122 of FIG. 2 may comprise one or more processes, and/or numerous process operations, but claimed subject matter is not limited to any particular method of formation of one or more layers and/or one or more electrodes of component 100. However, in at least one embodiment, one or more solution processes may be utilized, such as one or more of the following: one or more ejection processes, including, for example, one or more dip coating processes, spray coating processes, curtain coating processes, screen printing processes, chemical bath deposition processes and/or successive ionic layer absorption and reaction processes, as just a few examples, but again, claimed subject matter is not so limited. Particular methods of formation of the components illustrated herein may be better understood when explained with reference to FIG. 3, below.

Referring now to FIG. 3, one embodiment of a technique for forming a solution processed transistor having a multilayer dielectric is illustrated by a flowchart, although claimed subject matter is not limited in scope in this respect. Such an embodiment may be employed to at least partially form a solution processed component, as described below. The flowchart illustrated in FIG. 3 may be used to form a component at least in part, such as component 100 of FIG. 1 and/or component 122 of FIG. 2, for example, although claimed subject matter is not limited in this respect. Likewise, the order in which the blocks are presented does not necessarily limit claimed subject matter to any particular order. Additionally, intervening blocks not shown may be employed without departing from the scope of claimed subject matter.

Flowchart 140 depicted in FIG. 3 may, in alternative embodiments, be implemented in a combination of hardware and software and/or firmware, such as part of a computer controlled formation system capable of forming one or more portions of a component, such as component 100 of FIG. 1 and/or component 122 of FIG. 2, for example, and may comprise discrete and/or continual operations. In this embodiment, at block 142, one or more inorganic materials may be deposited on or over at least a portion of substrate, such as substrate 102 and/or 122, for example, and/or may be deposited over one or more other layers of components 100 and/or 120, such as the channel layer and/or one or more electrodes, as just a few examples. At block 144, a portion of the one or more inorganic materials may be processed, such as by selectively removing at least a portion of the one or more organic materials, and/or altering at least a portion of the one or more inorganic materials, explained in more detail later. At block 146, one or more inorganic materials may be deposited on or over at least a portion of the one or more inorganic materials deposited at block 142 and/or over one or more other layers described previously. At block 148, similar to block 144, a portion of the one or more inorganic materials may be processed, such as by selectively removing at least a portion of the one or more organic materials, and/or altering at least a portion of the one or more inorganic materials, explained in more detail later.

In this embodiment, at block 142, one or more inorganic materials may be deposited on or over at least a portion of a component, such as on one or more layers of a multilayer component, such as component 100 and/or 120, including, for example, a substrate layer, a channel layer, and/or an electrode layer, as just a few examples. As illustrated in FIG. 1, one or more inorganic dielectric materials may be deposited such that at least a portion of a dielectric layer, such as dielectric layer 108, is formed. In this embodiment, one or more inorganic materials, including SiOₓ, AlOₓ, ZrOₓ, HfOₓ, SiNₓ, SiOₓN_{y}, GeOₓ, GaOₓ, SbOₓ, SnOx, TiOx, YOx, LaOx, BaₐSr_{b}TiOx, BaₐZr_{b}TiOx, TaOₓ, and combinations thereof, for example, may be formed on or over at least a portion of one or more component layers, such as at least a portion of electrode layer 106, and/or at least a portion of the channel layer 104, and/or at least a portion of the substrate layer 102, although claimed subject matter is not limited in this respect. Additionally, deposition of one or more inorganic materials may comprise one or more solution processes, including, for example, one or more ejection processes, such as one or more jetting processes, including thermal and/or piezo jetting, such as by use of an ink jet component, including a thermal ink jet (TIJ) component, for example. Additionally, one or more inorganic materials may be deposited by use of one or more other solution processes, such as one or more contact printing processes and/or one or more coating processes, such as one or more spin coating processes. Additionally, although numerous materials or combinations of materials may be utilized to form a layer of inorganic material, and the material(s) utilized may depend, at least in part, on the particular process(es) utilized, in one embodiment, the inorganic material may substantially comprise zirconium oxide, and may be deposited by use of one or more thermal jetting processes, as just an example. Additionally, the one or more materials deposited may be in one or more forms, such as in a substantially liquid form, in a nanoparticle suspension form, and/or one or more types of precursor forms, as just a few examples. Additionally, the material(s) deposited may be deposited to a thickness, although the particular thickness may depend at least in part on one or more factors, such as the material(s) utilized to form the one or more sub-layers, the solution concentration, the number of sub-layers being formed, and/or the particular component being formed, for example.

In this embodiment, at block 144, at least a portion of the one or more materials deposited at block 142 may be processed, although, in alternative embodiments, no processing may be performed, for example. Additionally, particular processing performed on the one or more materials may be selected based at least in part on the material(s) utilized to form the material layer, for example, and/or the particular component being formed, for example. In one embodiment, at least a portion of the one or more inorganic materials may be at least partially removed, such as by use of one or more laser ablation and/or chemical etching processes, for example, which may result in at least a portion of the one or more materials being patterned, for example. Additionally, one or more portions may be altered, such as by being cured and/or sintered, for example. Curing, when used in this context, refers generally to a process wherein a liquid precursor is substantially transformed into a substantially solid film, such as an oxide film, and may comprise one or more solvent and/or organic group removal processes, and/or one or more decomposition of metal organic compound processes as a result from heating, for example, such as thermal, laser, microwave and/or other types of radiative heating. Additionally, sintering, when used in this context, refers generally to a process wherein multiple portions of a material, such as a metal oxide material in the form of nanoparticles, for example, may become a substantially singular mass, as a result of melting and recrystallization, such as result from heating, for example, such as thermal and/or laser heating. Additionally, one or more portions of one or more materials may be altered by being at least partially solidified, crystallized, polymerized, patterned, and/or having the density altered, but, again, particular processing performed on the one or more materials may be selected based at least in part on the material(s) utilized to form the material layer, for example, and/or the particular component being formed, for example.

In this embodiment, at block 146, one or more inorganic materials may be deposited on at least a portion of a component, such as on one or more inorganic materials deposited at block 142, for example. In this embodiment, one or more inorganic materials may comprise one or more amorphous and/or glass-like materials including one or more metal-oxy-hydroxy-salts, one or more types of glass, including solution processed silicate glasses, alkaline doped silicate glasses, sodium silicates, phosphosilicates, borosilicates, aluminosilicates, oxycarbide glasses, polysiloxanes, one or more glass resins including silsesquioxanes, hafnium-oxy-hydroxy-sulfate (HfOₓ(OH)_{y}(SO₄)_{z}), and combinations thereof, as just a few examples, and may be formed on at least a portion of the inorganic material deposited at block 142, although claimed subject matter is not limited in this respect, and at least a portion of the inorganic material may be deposited on one or more other component and/or material layers, for example. Deposition of one or more inorganic materials may comprise one or more solution processes, including, for example, one or more ejection processes, such as one or more jetting processes, including thermal and/or piezo jetting, such as by use of an ink jet component, including a TIJ component, for example. Additionally, one or more inorganic materials may be deposited by use of one or more solution processes, such as one or more of the processes described with reference to block 142, for example. Additionally, although numerous materials or combinations of materials may be utilized to form a layer of inorganic material, and the material(s) utilized may depend, at least in part, on the particular process(es) utilized, in one embodiment, the inorganic material may substantially comprise hafnium-oxy-hydroxy-sulfate, and may be deposited by use of an ejection mechanism, for example.

However, continuing with this embodiment, at block 148, at least a portion of the one or more materials deposited at block 146 may be processed, although, in alternative embodiments, no processing may be performed, for example. Additionally, particular processing performed on the one or more materials may be selected based at least in part on the material(s) utilized to form the material layer, for example, and/or the particular component being formed, for example. In one embodiment, at least a portion of the one or more inorganic materials may be at least partially removed, such as by use of one or more laser ablation processes, for example, which may result in at least a portion of the one or more materials being patterned, for example. Additionally, one or more portions may be cured and/or sintered, for example. Thus, a component comprising a dielectric layer, wherein the dielectric layer comprises multiple inorganic materials deposited by use of solution processing may be formed, and the component may exhibit one or more characteristics, such as described previously.

As described in some detail previously, such as a dielectric layer wherein at least a portion of the dielectric layer comprises two or more layers of inorganic material, and at least a portion of the two or more layers may be solution processed may result in the formation of a dielectric layer, and/or a component having particular characteristics that may vary from a component not being formed in this manner and/or from this particular combination of materials. For example, a dielectric layer of a thin film transistor may be formed in this manner, and may result in the formation of a thin film transistor having desirable characteristics, such as by having desirable physical, chemical and/or electrical properties, including, for example, electrical interface properties such as mobility, stability and/or turn-on voltages, electrical integrity properties including breakdown field properties and/or current leakage properties, desirable film quality, channel mobility capabilities, and/or charge transport properties, which may aid reliability, for example, and/or desirable processability properties, as just a few examples. However, it is worthwhile to note that one or more embodiments described herein are not limited in this respect, and may have differing and/or additional properties as compared to those described above, for example.

It is now appreciated, based at least in part on the foregoing disclosure, that a combination of hardware and software and/or firmware may be produced capable of performing a variety of operations described with reference to FIG. 3, which may be implemented in a system suitable for forming a component having a multilayer dielectric layer, as described previously. It will additionally be understood that, although particular embodiments have just been described, claimed subject matter is not limited in scope to a particular embodiment or implementation. For example, a system capable of implementing one or more of the foregoing operations described in reference to FIG. 3 may comprise hardware, such as implemented to operate on a device or combination of devices as previously described, for example, whereas another embodiment may be in software and hardware, for example. Likewise, an embodiment of a system capable of implementing one or more of the abovementioned operations may be implemented in firmware, or as any combination of hardware and software and/or firmware, for example. Additionally, all or a portion of one embodiment may be implemented to operate at least partially in one device, such as an ejection device, a laser device, a display, a computing device, a set top box, a cell phone, and/or a personal digital assistant (PDA), for example. Likewise, although claimed subject matter is not limited in scope in this respect, one embodiment may comprise one or more articles, such as a storage medium or storage media. This storage media, such as, one or more CD-ROMs and/or disks, for example, may have stored thereon instructions, that when executed by a system, such as a computer system, computing platform, a set top box, a cell phone, and/or a personal digital assistant (PDA), and/or other system, for example, may result in an embodiment of a method in accordance with claimed subject matter being executed, such as one of the embodiments previously described, for example. As one potential example, a computing platform may include one or more processing units or processors, one or more input/output devices, such as a display, a keyboard and/or a mouse, and/or one or more types of memory, such as static random access memory, dynamic random access memory, flash memory, and/or a hard drive, although, again, claimed subject matter is not limited in scope to this example.

In the preceding description, various aspects of claimed subject matter have been described. For purposes of explanation, specific numbers, systems and/or configurations were set forth to provide a thorough understanding of claimed subject matter. However, it should be apparent to one skilled in the art having the benefit of this disclosure that claimed subject matter may be practiced without the specific details. In other instances, well-known features were omitted and/or simplified so as not to obscure claimed subject matter. While certain features have been illustrated and/or described herein, many modifications, substitutions, changes and/or equivalents will now occur to those skilled in the art. It is, therefore, to be understood that the appended claims are intended to cover all such modifications and/or changes as fall within the true spirit of claimed subject matter.

1. A method, comprising:
depositing a first inorganic dielectric material over at least a portion of a substrate by use of one or more solution processes;
depositing a second inorganic dielectric material over and/or in contact with at least a portion of said first inorganic dielectric material by use of one or more solution processes, wherein said second inorganic dielectric material is substantially amorphous and/or glass-like, to form at least a portion of a dielectric layer of a thin film transistor.

2. The method of claim 1, and further comprising forming a channel layer over at least a portion of the substrate, wherein said channel layer is formed such that at least a portion of the first inorganic dielectric material is in contact with at least a portion of said channel layer.

3. The method of claim 1, and further comprising:
processing at least a portion of said first and second inorganic dielectric materials subsequent to the respective depositing of each material.

4. The method of claim 3, wherein said processing substantially comprises one or more of the following: curing, evaporation, solidification, ablation, crystallization, removal, polymerization, densification, and patterning.

5. The method of claim 1, wherein said one or more solution processes comprises one or more of the following: ejection, including ink jetting, contact printing, spin coating, dip coating, spray coating, screen printing, chemical bath deposition and successive ionic layer absorption and reaction.

6. The method of claim 5, wherein said depositing said first inorganic dielectric material and said depositing said second inorganic dielectric material are substantially performed by differing solution processes.

7. The method of claim 1, wherein said first inorganic dielectric material comprises one or more of: SiOₓ, AlOₓ, ZrOₓ, HfOₓ, SiNₓ, SiOₓN_{y}, GeOₓ, GaOₓ, SbOₓ, SnOx, TiOx, YOx, LaOx, BaₐSr_{b}TiOx, BaₐZr_{b}TiOx, TaOₓ, and combinations thereof,

8. The method of claim 1, wherein said second inorganic dielectric material comprises one or more of: metal-oxy-hydroxy-salts, one or more types of glass, including solution processed silicate glasses, alkaline doped silicate glasses, sodium silicates, phosphosilicates, borosilicates, aluminosilicates, oxycarbide glasses and polysiloxanes, one or more glass resins including silsesquioxanes, hafnium-oxy-hydroxy-sulfate HfOₓ(OH)_{y}(SO₄)_{z}) and combinations thereof.

9. The method of claim 2, and further comprising:
forming a source and drain electrode over at least a portion of the substrate; and
forming a gate electrode over at least a portion of the substrate, wherein said source and drain electrodes are formed over at least a portion of said substrate and/or said channel layer, said first inorganic dielectric material is formed over at least a portion of said channel layer and/or said source and drain electrodes, said second inorganic dielectric material is formed over at least a portion of said first inorganic dielectric material, and said gate electrode is formed over at least a portion of said second inorganic dielectric such as to form at least a portion of a top gate thin film transistor.

10. The method of claim 2, and further comprising:
forming a source and drain electrode over at least a portion of the substrate; and
forming a gate electrode over at least a portion of the substrate, wherein said gate electrode is formed on said substrate, said second inorganic dielectric material is formed on at least a portion of said gate electrode and/or said substrate, said first inorganic dielectric material is formed on at least a portion of said second inorganic dielectric material, and said source and drain electrodes are formed on at least a portion of said first inorganic dielectric material, and said channel layer is formed on at least a portion of said first inorganic dielectric material and/or said source and drain electrodes, such as to form at least a portion of a bottom gate thin film transistor.

11. A method, comprising:
a step for depositing a first inorganic dielectric material over at least a portion of a substrate by use of one or more steps for solution processing;
a step for processing at least a portion of said first inorganic dielectric material;
a step for depositing a second inorganic dielectric material over and/or in contact with said at least a portion of said first inorganic dielectric material by use of one or more steps for solution processing, wherein said second inorganic dielectric material is substantially amorphous and/or glass-like; and
a step for processing at least a portion of said second inorganic dielectric material, to form at least a portion of a dielectric layer of a thin film transistor.

12. The method of claim 11, and further comprising forming a channel layer over at least a portion of the substrate, wherein said channel layer is formed such that at least a portion of the first inorganic dielectric material is in contact with at least a portion of the channel layer.

13. The method of claim 11, wherein said step for processing substantially comprises one or more of the following: curing, evaporation, solidification, ablation, crystallization, removal, polymerization, densification and patterning.

14. The method of claim 11, wherein one or more of said steps for solution processing comprises one or more of the following: ejection, including ink jetting, contact printing, spin coating, dip coating, spray coating, screen printing, chemical bath deposition and successive ionic layer absorption and reaction.

15. The method of claim 14, wherein said steps for depositing said first inorganic dielectric material and said depositing said second inorganic dielectric material comprise differing steps for solution processing.

16. The method of claim 11, wherein said first inorganic dielectric material comprises one or more of: SiOₓ, AlOₓ, ZrOₓ, HfOₓ, SiNₓ, SiOₓN_{y}, GeOₓ, GaOₓ, SbOₓ, SnOx, TiOx, YOx, LaOx, BaₐSr_{b}TiOx, BaₐZr_{b}TiOx, TaOₓ, and combinations thereof.

17. The method of claim 11, wherein said second inorganic dielectric material comprises one or more of: metal-oxy-hydroxy-salts, one or more types of glass, including solution processed silicate glasses, alkaline doped silicate glasses, sodium silicates, phosphosilicates, borosilicates, aluminosilicates, oxycarbide glasses and polysiloxanes, one or more glass resins including silsesquioxanes, hafnium-oxy-hydroxy-sulfate HfOₓ(OH)_{y}(SO₄)_{z}) and combinations thereof.

18. The method of claim 12, and further comprising:
a step for forming a source and drain electrode over at least a portion of the substrate; and
a step for forming a gate electrode over at least a portion of the substrate, wherein said source and drain electrodes are formed on at least a portion of said substrate and/or said channel layer, said first inorganic dielectric material is formed on at least a portion of said channel layer and/or said source and drain electrodes, said second inorganic dielectric material is formed on at least a portion of said first inorganic dielectric material, and said gate electrode is formed on at least a portion of said second inorganic dielectric layer whereby at least a portion of a top gate thin film transistor is formed.

19. The method of claim 12, and further comprising:
a step for forming a source and drain electrode over at least a portion of the substrate; and
a step for forming a gate electrode over at least a portion of the substrate, wherein said gate electrode is formed on said substrate, said second inorganic dielectric material is formed on at least a portion of said gate electrode and/or said substrate, said first inorganic dielectric material is formed on at least a portion of said second inorganic dielectric material, and said source and drain electrodes are formed on at least a portion of said first inorganic dielectric material, and said channel layer is formed on at least a portion of said first inorganic dielectric material and/or said source and drain electrodes, such as to form at least a portion of a bottom gate thin film transistor.

20. An apparatus, comprising:
a thin film transistor (TFT) having a substrate, at least one channel layer, a plurality of electrodes and a dielectric layer, wherein said dielectric layer substantially comprises a first dielectric material and a second dielectric material, wherein said first dielectric material substantially comprises one or more metal oxides, wherein said second dielectric material substantially comprises amorphous inorganic material, and wherein said first dielectric material is in contact with at least a portion of the channel layer, and said second dielectric material is in contact with at least a portion of said first dielectric material.

21. The apparatus of claim 20, wherein at least a portion of said first and second dielectric materials are deposited by utilizing one or more solution processes, including ejection, including ink jetting, contact printing, spin coating, dip coating, spray coating, screen printing, chemical bath deposition and successive ionic layer absorption and reaction.

22. The apparatus of claim 21, wherein said first and said second dielectric materials are deposited by use of differing solution processes.

23. The apparatus of claim 20, wherein said first dielectric material comprises one or more of: SiOₓ, AlOₓ, ZrOₓ, HfOₓ, SiOₓN_{y}, GeOₓ, GaOₓ, SbOₓ, SnOx, TiOx, YOx, LaOx, BaₐSr_{b}TiOx, BaₐZr_{b}TiOx, TaOₓ, and combinations thereof.

24. The apparatus of claim 20, wherein said second dielectric material comprises one or more of: metal-oxy-hydroxy-salts, one or more types of glass, including solution processed silicate glasses, alkaline doped silicate glasses, sodium silicates, phosphosilicates, borosilicates, aluminosilicates, oxycarbide glasses and polysiloxanes, one or more glass resins including silsesquioxanes, hafnium-oxy-hydroxy-sulfate HfOₓ(OH)_{y}(SO₄)_{z}) and combinations thereof.

25. The apparatus of claim 20, wherein said TFT substantially comprises a bottom gate transistor.

26. The apparatus of claim 20, wherein said TFT substantially comprises a top gate transistor.

27. An apparatus, comprising:
means for forming a thin film transistor (TFT) having a substrate, at least one channel layer, a plurality of electrodes and a dielectric layer, wherein said dielectric layer substantially comprises a first dielectric material and a second dielectric material, wherein said first dielectric material substantially comprises one or more metal oxides, wherein said second dielectric material substantially comprises amorphous inorganic material, and wherein said first dielectric material is in contact with at least a portion of the channel layer, and said second dielectric material is in contact with at least a portion of said first dielectric material.

28. The apparatus of claim 27, wherein at least a portion of said first and second dielectric materials are deposited by one or more means for solution processing, including ejection, including ink jetting, contact printing, spin coating, dip coating, spray coating, screen printing, chemical bath deposition and successive ionic layer absorption and reaction.

29. The apparatus of claim 28, wherein said first and said second dielectric materials are deposited by us of differing means for solution processing.

30. The apparatus of claim 27, wherein said first dielectric material comprises one or more of: SiOₓ, AlOₓ, ZrOₓ, HfOₓ, SiOₓN_{y}, GeOₓ, GaOₓ, SbOₓ, SnOx, TiOx, YOx, LaOx, BaₐSr_{b}TiOx, BaₐZr_{b}TiOx, TaOₓ, and combinations thereof.

31. The apparatus of claim 27, wherein said second dielectric material comprises one or more of: metal-oxy-hydroxy-salts, one or more types of glass, including solution processed silicate glasses, alkaline doped silicate glasses, sodium silicates, phosphosilicates, borosilicates, aluminosilicates, oxycarbide glasses and polysiloxanes, one or more glass resins including silsesquioxanes, hafnium-oxy-hydroxy-sulfate HfOₓ(OH)_{y}(SO₄)_{z}) and combinations thereof.

32. The apparatus of claim 27, wherein said TFT substantially comprises a bottom gate transistor.

33. The apparatus of claim 27, wherein said TFT substantially comprises a top gate transistor.

34. A thin film transistor (TFT), formed substantially by a process comprising:
a step for depositing a first material over at least a portion of a substrate utilizing one or more steps for solution processing to form a first portion of a dielectric layer, said first material substantially comprising a first inorganic dielectric material;
a step for depositing a second material over and/or in contact with said at least a portion of said first portion of a dielectric layer by use of one or more steps for solution processing to form a second portion of a dielectric layer, said second material substantially comprising a substantially amorphous second inorganic dielectric material, to form at least a portion of a dielectric layer of a thin film transistor.

35. The TFT of claim 34, and further comprising a step for forming a channel layer over at least a portion of the substrate, wherein said channel layer is formed such that at least a portion of the first portion of a dielectric layer is in contact with at least a portion of the channel layer.

36. The TFT of claim 34, and further comprising:
a step for processing at least a portion of said first and second portions of a dielectric layer subsequent to the respective depositing of each material.

37. The TFT of claim 36, wherein said step for processing substantially comprises one or more of the following: curing, evaporation, solidification, ablation, crystallization, removal, polymerization, densification, and/or patterning.

38. The TFT of claim 34, wherein said one or more steps for solution processing comprises one or more of the following: ejection, including ink jetting, contact printing, spin coating, dip coating, spray coating, screen printing, chemical bath deposition and successive ionic layer absorption and reaction.

39. The TFT of claim 38, wherein said steps for depositing said first material and said second material substantially comprises differing steps for solution processing.

40. The TFT of claim 34, wherein said first material comprises one or more of: SiOₓ, AlOₓ, ZrOₓ, HfOₓ, SiNₓ, SiOₓN_{y}, GeOₓ, GaOₓ, SbOₓ, SnOx, TiOx, YOx, LaOx, BaₐSr_{b}TiOx, BaₐZr_{b}TiOx, TaOₓ, and combinations thereof.

41. The TFT of claim 34, wherein said second material comprises one or more of: metal-oxy-hydroxy-salts, one or more types of glass, including solution processed silicate glasses, alkaline doped silicate glasses, sodium silicates, phosphosilicates, borosilicates, aluminosilicates, oxycarbide glasses and polysiloxanes, one or more glass resins including silsesquioxanes, hafnium-oxy-hydroxy-sulfate HfOₓ(OH)_{y}(SO₄)_{z}) and combinations thereof.

42. The TFT of claim 35, and further comprising:
a step for forming a source and drain electrode over at least a portion of the substrate; and
a step for forming a gate electrode over at least a portion of the substrate, wherein said source and drain electrodes are formed on at least a portion of said substrate and/or said channel layer, said first portion of a dielectric layer is formed on at least a portion of said channel layer and/or said source and drain electrodes, said second portion of a dielectric layer is formed on at least a portion of said first portion of a dielectric layer, and said gate electrode is formed on at least a portion of said second portion of a dielectric layer such as to form at least a portion of a top gate thin film transistor.

43. The TFT of claim 35, and further comprising:
a step for forming a source and drain electrode over at least a portion of the substrate; and
a step for forming a gate electrode over at least a portion of the substrate, wherein said gate electrode is formed on said substrate, said second portion of a dielectric layer is formed on at least a portion of said gate electrode and/or said substrate, said first portion of a dielectric layer is formed on at least a portion of said portion of a dielectric layer, and said source and drain electrodes are formed on at least a portion of said first portion of a dielectric layer, and said channel layer is formed on at least a portion of said first portion of a dielectric layer and/or said source and drain electrodes, such as to form at least a portion of a bottom gate thin film transistor.
